(19) United States
(12) Patent Application Publication
(10) Pub. No.: US 2009/0020801 A1
(43) Pub. Date: Jan. 22, 2009

(54) TWO-BIT FLASH MEMORY CELL STRUCTURE AND METHOD OF MAKING THE SAME

(76) Inventors: Wei-Ming Liao, Taipei City (TW); Ming-Cheng Chang, Taipei County (TW); Jer-Chyi Wang, Taoyuan County (TW)

Correspondence Address: NORTH AMERICA INTELLECTUAL PROPERTY CORPORATION, P.O. BOX 506, MERRIFIELD, VA, 22116, US

(21) Appl. No.: 11/951,344

(22) Filed: Dec. 6, 2007

(30) Foreign Application Priority Data
Jul. 18, 2007 (TW) 096126211

(51) Int. Cl. H01L 29/788; H01L 21/336

(52) U.S. Cl. 257/316; 438/261; 257/E29.3; 257/E21.422

(57) ABSTRACT

A flash memory cell includes a control gate oxide layer on a substrate, a T-shaped control gate on the control gate oxide layer, a floating gate disposed on two recessed sidewalls of the T-shaped control gate, an insulating layer between the control gate and the floating gate, a dielectric layer between the floating gate and the substrate, a spacer on the sidewall of the floating gate, a P⁺ source/drain region next to the spacer, and an N⁺ pocket region encompassing the P⁺ source/drain region and covering the area directly under the floating gate.

### BACKGROUND OF THE INVENTION

1. Field of the Invention

The present invention relates generally to the field of memory devices. More particularly, the present invention relates to a two-bit flash memory cell structure and method of making the same.

2. Description of the Prior Art

Flash memory is a non-volatile computer memory that can be electrically erased and reprogrammed. It is a technology that is primarily used in, for example, memory cards or USB flash drives, which are used for general storage and transfer of data between computers and other digital products. Presently, scaling down of flash memory cells has been considered critical in continuing the trend toward higher device density.

Please refer to FIGS. 1-6. FIGS. 1-6 are schematic, cross-sectional views showing the process for making a flash memory cell according to the prior art. As shown in FIG. 1, a liner layer 12, a polysilicon layer 14 and a silicon nitride cap layer 16 are sequentially formed on a substrate 10. The substrate 10 may be a semiconductor substrate such as silicon substrate. An opening 16a is formed in the silicon nitride cap layer 16 to expose the polysilicon layer 14, which defines the position and pattern of the control gate of the flash memory cell.

As shown in FIG. 2, an etching process is carried out to etch the exposed polysilicon layer 14 and the silicon nitride cap layer 16 through the opening 16a, thereby forming a cavity 18 that exposes a portion of the substrate 10. The aforesaid etching process is typically an anisotropic dry etching process.

As shown in FIG. 3, an oxidation process is performed to form a control gate oxide layer 20 on the exposed substrate 10 within the cavity 18. Subsequently, an insulating layer 22 such as an oxide-nitride-oxide (ONO) dielectric layer is formed on the silicon nitride cap layer 16 and on the interior surfaces of the cavity 18 including the top surface of the control gate oxide layer 20. Thereafter, a polysilicon layer 24 is blanket deposited on the substrate 10 to fill the cavity 18 and cover the insulating layer 22.

As shown in FIG. 4 and taking FIG. 3 for reference, a chemical mechanical polishing (CMP) process is performed to remove the excessive polysilicon layer 24 and the insulating layer 22 outside the cavity 18, thereby exposing the silicon nitride cap layer 16 and forming a control gate 30.

As shown in FIG. 5, subsequently, the silicon nitride cap layer 16 is selectively removed to expose the polysilicon layer 14. A conformal spacer layer 32 such as silicon nitride is then deposited on the protruding control gate 30 after the silicon nitride cap layer 16 is removed.

As shown in FIG. 6, an anisotropic dry etching process is carried out to etch the spacer layer 32, thereby forming a spacer 34. The anisotropic dry etching process continues and the underlying polysilicon layer 14 is etched to form floating gates 40 underneath the spacer 34 in a self-aligned fashion. An ion implantation process 50 is then performed to form source/drain regions 44 in the substrate 10.

The above-described prior art two-bit memory cell has shortcomings. For example, punchthrough problem due to boron diffusion that occurs between source and drain of a PMOS two-bit memory cell becomes worse when the size of the cell continues to shrink. Besides, the coupling ratio between the control gate and the floating gate of the above-described conventional two-bit memory cell is not satisfactory.

In light of the above, the electrical performance of the above-described two-bit memory cell needs to be improved and the aforesaid shortcomings need to be overcome. It is desired to develop novel memory cell structure and method of fabrication of the same in order to solve the aforesaid punchthrough problem, increase the coupling ratio and improve the electrical performance of the memory devices.

### SUMMARY OF THE INVENTION

It is one objective of the present invention to provide improved two-bit flash memory cell structure and method of making the same in order to solve the above-mentioned prior art problems.

According to the claimed invention, a method for fabricating a flash memory device is provided. A substrate having thereon a dielectric layer and a first silicon layer is provided. A cavity is formed in the first silicon layer and the dielectric layer to expose a portion of the substrate. A control gate oxide layer is formed on the exposed substrate within the cavity. An insulating layer is formed on an interior surface of the cavity and on the first silicon layer. A second silicon layer is formed on the insulating layer, wherein the second silicon layer fills the cavity. A photoresist pattern is formed on the second silicon layer. An etching process is performed to etch the second silicon layer, the insulating layer and the first silicon layer not covered by the photoresist pattern, thereby forming a T-shaped control gate and a floating gate. A tilt-angle ion implantation process is performed to form an N⁺ pocket doping region under the floating gate. A spacer is formed on a sidewall of the floating gate. A heavy ion implantation process is performed to form a P⁺ source/drain region in the substrate next to the spacer.

The present invention discloses a flash memory cell, comprising a substrate; a control gate oxide layer on the substrate; a T-shaped control gate on the control gate oxide layer; a floating gate disposed on two recessed sidewalls of the T-shaped control gate; an insulating layer between the control gate and the floating gate; a dielectric layer between the floating gate and the substrate; a spacer on a sidewall of the floating gate; a P⁺ source/drain region in the substrate next to the spacer; and an N⁺ pocket region encompassing the P⁺ source/drain region and covering an area directly under the floating gate.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-6 are schematic, cross-sectional views showing the process for making a flash memory cell according to the prior art.

FIGS. 7-12 are schematic, cross-sectional views showing the process for making an exemplary PMOS flash memory cell according to the preferred embodiment of this invention.

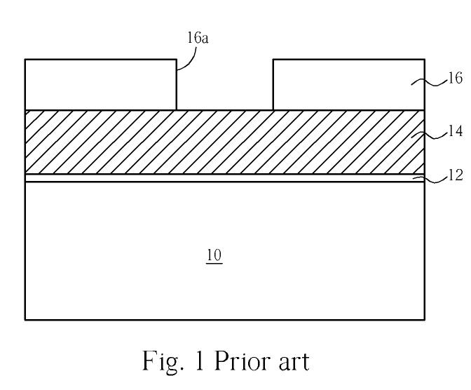

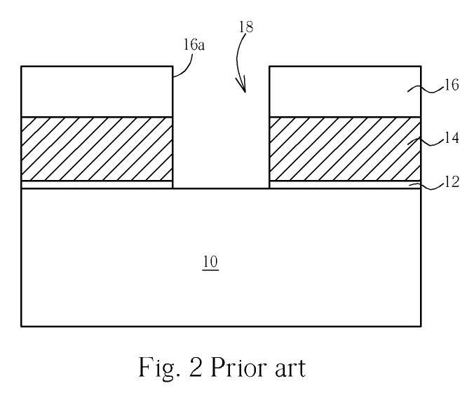

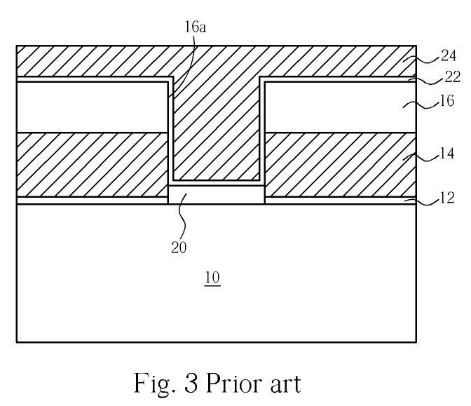

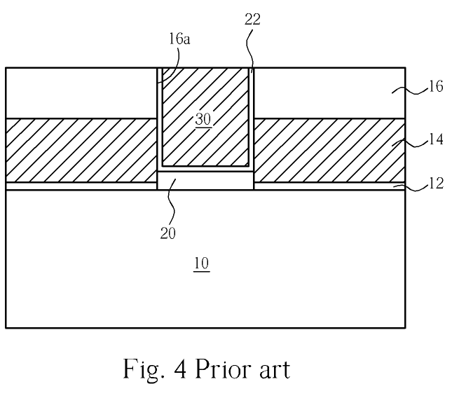

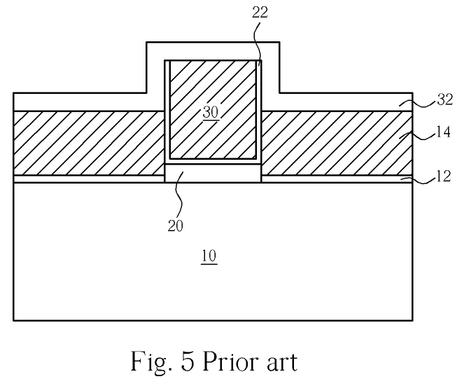

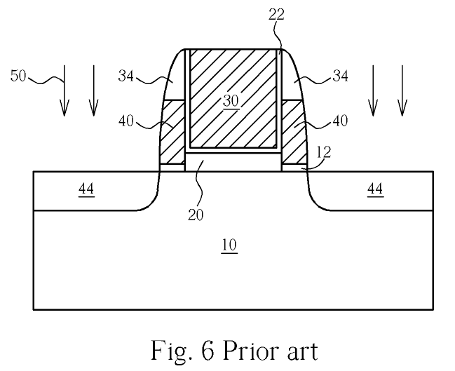

### DETAILED DESCRIPTION

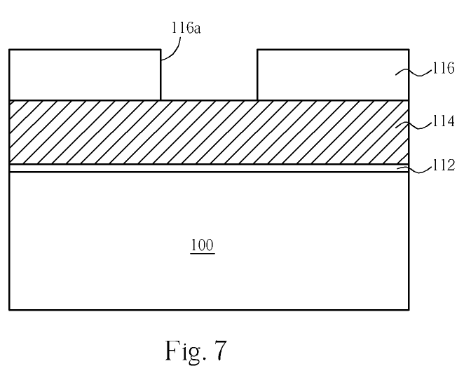

Please refer to FIGS. 7-12. FIGS. 7-12 are schematic, cross-sectional views showing the process for making an exemplary PMOS flash memory cell according to the preferred embodiment of this invention.

As shown in FIG. 7, a dielectric layer 112, a polysilicon layer 114 and a photoresist layer 116 are formed on a substrate 100. The substrate 100 may be a semiconductor substrate such as a P-type silicon substrate. An opening 116a is formed in the photoresist layer 116, which defines the position and pattern of the control gate of the flash memory cell. The dielectric layer 112 may be silicon oxide or any suitable dielectric materials.

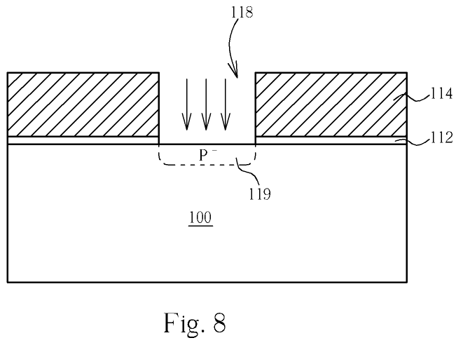

As shown in FIG. 8 and taking FIG. 7 for reference, an etching process is carried out to etch the polysilicon layer 114 and the dielectric layer 112 through the opening 116a, thereby forming a cavity 118 and exposing a portion of the substrate 100. The aforesaid etching process is preferably an anisotropic dry etching process. A P-type ion implantation process is then performed to implant a P⁻ doping region 119 into the channel region in order to adjust the threshold voltage of the memory cell. The photoresist layer 116 is then removed.

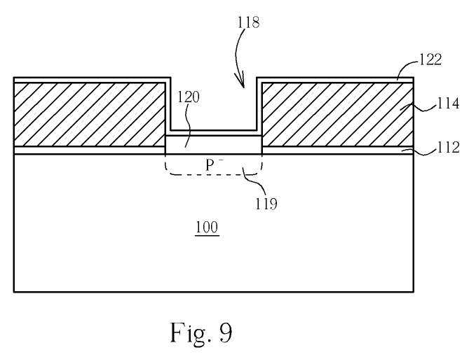

As shown in FIG. 9, an oxidation process is performed to form a control gate oxide layer 120 on the exposed substrate 100 within the cavity 118. Subsequently, a conformal insulating layer 122 such as oxide-nitride-oxide (ONO) dielectric layer is formed on the interior surfaces of the cavity 118 and on the polysilicon layer 114.

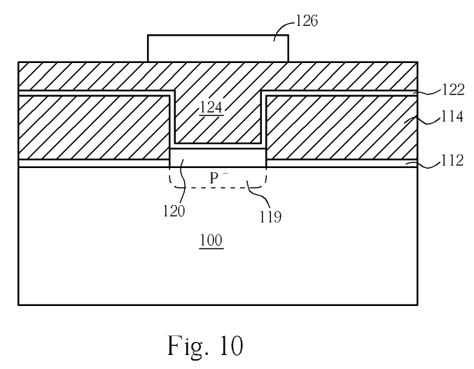

As shown in FIG. 10, a polysilicon layer 124 is blanket deposited on the substrate 100. The polysilicon layer 124 fills the cavity 118 and covers the insulating layer 122. A photoresist pattern 126 is formed on the polysilicon layer 124. The photoresist pattern 126 defines the pattern of a T-shaped control gate and position of the floating gates.

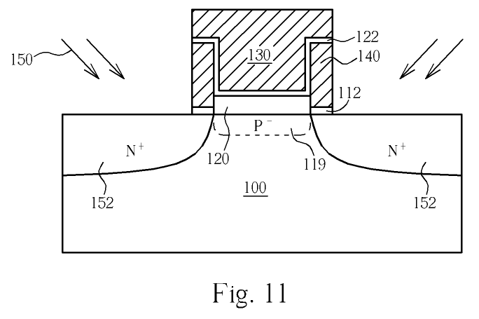

As shown in FIG. 11 and using FIG. 10 for reference, an anisotropic dry etching process is then performed, using the photoresist pattern 126 as an etching hard mask, to etch the polysilicon layer 124, the insulating layer 122, the polysilicon layer 114 and the dielectric layer 112 not covered by the photoresist pattern 126, thereby forming a T-shaped control gate 130 and floating gates 140. The floating gates 140 are inlaid into recessed sidewalls of the T-shaped control gate 130. Thereafter, a tilt-angle ion implantation process 150 is performed to implant N type dopants such as phosphorus or arsenic, preferably arsenic, into the substrate 100 underneath the floating gates 140, thereby forming N⁺ pocket doping regions 152.

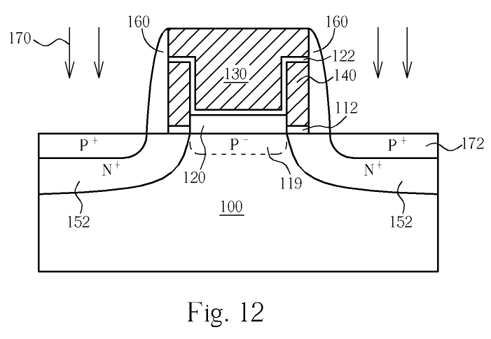

As shown in FIG. 12, a spacer 160 such as a silicon nitride spacer is then formed on a sidewall of the T-shaped control gate 130 and on the sidewall of the floating gate 140. A heavy ion implantation process 170 is performed, using the T-shaped control gate 130 and the spacer 160 as implant mask, to implant P type dopants such as boron into the substrate 100 next to the spacer 160, thereby forming P⁺ source/drain regions 172.

The present invention is characterized in that, as shown in FIG. 12, the T-shaped control gate 130 is capable of increasing the coupling ratio between the control gate and the floating gate. By utilizing the T-shaped control gate 130, the total height of the gate can be reduced, which facilitates the subsequent tilt-angle ion implantation process and the formation of the N⁺ pocket doping regions 152.

Structurally, the present invention features the N⁺ pocket doping regions 152 that extends to the substrate area that is directly under the floating gates 140, as shown in FIG. 12. The extended N⁺ pocket doping regions 152 under the floating gate is capable of inhibiting boron diffusion and solving the punchthrough problem due to boron diffusion between the source and drain of the PMOS memory transistor.

Those skilled in the art will readily observe that numerous modifications and alterations of the device and method may be made while retaining the teachings of the invention.

What is claimed is:

1. A method for fabricating a flash memory device, comprising:
providing a substrate having thereon a dielectric layer and a first silicon layer;
forming a cavity in the first silicon layer and the dielectric layer to expose a portion of the substrate;
forming a control gate oxide layer on the exposed substrate within the cavity;
forming an insulating layer on interior surface of the cavity and on the first silicon layer;
forming a second silicon layer on the insulating layer, wherein the second silicon layer fills the cavity;
forming a photoresist pattern on the second silicon layer;
performing an etching process to etch the second silicon layer, the insulating layer and the first silicon layer not covered by the photoresist pattern, thereby forming a T-shaped control gate and a floating gate;
performing a tilt-angle ion implantation process to form an N⁺ pocket doping region under the floating gate;
forming a spacer on a sidewall of the floating gate; and
performing a heavy ion implantation process to form a P⁺ source/drain region in the substrate next to the spacer.

2. The method according to claim 1, wherein the dielectric layer comprises a silicon oxide layer.

3. The method according to claim 2, wherein the first silicon layer comprises polysilicon.

4. The method according to claim 3, wherein the second silicon layer comprises polysilicon.

5. The method according to claim 4, wherein the spacer comprises silicon nitride.

6. The method according to claim 5, wherein dopants used in the tilt-angle ion implantation process comprises arsenic.

7. The method according to claim 6, wherein the insulating layer comprises oxide-nitride-oxide (ONO) dielectric layer.

8. A flash memory cell, comprising:
a substrate;
a control gate oxide layer on the substrate;
a T-shaped control gate on the control gate oxide layer;
a floating gate disposed on two recessed sidewalls of the T-shaped control gate;
an insulating layer between the control gate and the floating gate;
a dielectric layer between the floating gate and the substrate;
a spacer on a sidewall of the floating gate;
a P⁺ source/drain region in the substrate next to the spacer; and
an N⁺ pocket region encompassing the P⁺ source/drain region and covering an area directly under the floating gate.

9. The flash memory cell according to claim 8, wherein the substrate comprises P type substrate.

10. The flash memory cell according to claim 9, wherein the dielectric layer comprises silicon oxide layer.

11. The flash memory cell according to claim 10, wherein the spacer comprises silicon nitride.

12. The flash memory cell according to claim 11, wherein the insulating layer comprises oxide-nitride-oxide (ONO) dielectric layer.
